(19) United States
(12) Patent Application Publication
(10) Pub. No.: US 2026/0096076 A1
(43) Pub. Date: Apr. 2, 2026

(54) ELECTRONIC DEVICE ENCLOSURE HAVING A PLURALITY OF SURFACE FEATURES

(71) Applicant: Sandisk Technologies, Inc., Milpitas, CA (US)

(72) Inventors: Fu Xing Chan, Penang (MY); Chun Sean Lau, Penang (MY); MyungJin Kim, Santa Clara, CA (US); Bo Yang, Dublin, CA (US); Lihwa Fong, Irvine, CA (US); Pardeep Kumar Bhatti, Gilbert, AZ (US); Ning Ye, San Jose, CA (US)

(21) Appl. No.: 18/902,041

(22) Filed: Sep. 30, 2024

(51) Int. Cl. H05K 9/00

(52) U.S. Cl. CPC H05K 9/0052

(57) ABSTRACT

An enclosure for an electronic device includes one or more surface features that account for manufacturing tolerances associated with the enclosure. The enclosure includes a first portion and a second portion that mates with the first portion. The surface feature extends from a contact surface of the first portion of the enclosure and acts as a contact point between the first portion of the enclosure and the second portion of the enclosure. The surface feature helps ensure each portion of the enclosure remain in contact, which provides the electronic device optimal protection from electrical interference.

### BACKGROUND

A data storage device is often subjected to environments with high electromagnetic interference. The layout of circuits within the data storage device, as well as grounding path designs of the data storage device, help ensure a safe and reliable pathway through which electrical currents can pass without causing damage to sensitive electronic components and/or without disrupting electrical signals (which can lead to data corruption).

In addition to the layout of the circuits and grounding path designs, the enclosure of the data storage device also helps mitigate negative effects of electromagnetic interference. The enclosure mitigates negative effects of electromagnetic interference by having consistent contact between a printed circuit board (PCB) of the data storage device and the enclosure and by having consistent contact between each section or part of the enclosure. However, due to inherent manufacturing tolerances of the enclosure, contact between the enclosure and the PCB and/or contact between different sections of the enclosure may not always occur.

Accordingly, it would be beneficial for an enclosure of a data storage device to have features that account for manufacturing tolerances.

### SUMMARY

The present disclosure describes an enclosure for an electronic device such as, for example, a data storage device. In an example, the enclosure includes one or more surface features that account for manufacturing tolerances associated with the enclosure itself and/or manufacturing tolerances of components (e.g., screws, printed circuit boards (PCBs)) that are associated with the enclosure.

In one example, the enclosure includes a first portion (e.g., a top portion) and a second portion (e.g., a bottom portion). The first portion and the second portion are configured or adapted to mate with each other. The surface feature is provided on, or is otherwise associated with, a contact surface of the first portion of the enclosure and/or the second portion of the enclosure. In an example, the contact surface is located at or near a perimeter of the first portion of the enclosure and/or the second portion of the enclosure. The surface feature protrudes or extends from the contact surface of the first portion of the enclosure and/or the second portion of the enclosure and contacts the contact surface of the other of the first portion of the enclosure and/or the second portion of the enclosure.

In an example, the first portion of the enclosure and/or the second portion of the enclosure have a perimeter (or another section or portion) that is arranged in a stairstep configuration. In such examples, the surface feature is provided on a vertical contact surface of the stairstep configuration. In another example, the surface feature is provided on a horizontal contact surface of the stairstep configuration.

The surface feature may be a single surface feature that extends partially, substantially, or entirely along one contact surface of the enclosure. In other examples, the single surface feature, or multiple surface features, are provided around one or more contact surfaces of one or more of the portions of the enclosure.

Accordingly, examples of the present disclosure describe an enclosure for an electronic device that includes a first section and a second section. The first section has a first contact surface in a first stairstep configuration. Likewise, the second section has a second contact surface in a second stairstep configuration that mates with the first contact surface of the first section. The enclosure also includes a surface feature that extends from the first contact surface. In an example, the surface feature provides a contact point between the first contact surface and the second contact surface.

Examples also describe an enclosure for an electronic device that includes a first portion and a second portion adapted to mate with the first portion. The enclosure also includes a plurality of surface features extending from a perimeter of at least one of the first portion and the second portion. In an example, the plurality of surface features provide a contact point between the first portion and the second portion.

The present disclosure also describes an enclosure for an electronic device that includes a first section and a second section. The first section includes a first contact surface and the second section includes a second contact surface that mates with the first contact surface of the first section. The enclosure also includes a surface feature. The surface feature is associated with the first contact surface. In an example, the surface feature accounts for a manufacturing tolerance associated with at least one of the first section and the second section and provides a contact point between the first contact surface and the second contact surface.

This summary is provided to introduce a selection of concepts in a simplified form that are further described below in the Detailed Description. This summary is not intended to identify key features or essential features of the claimed subject matter, nor is it intended to be used to limit the scope of the claimed subject matter.

### BRIEF DESCRIPTION OF THE DRAWINGS

Non-limiting and non-exhaustive examples are described with reference to the following Figures.

FIG. 1 illustrates a cross-section view of an electronic device according to an example.

FIG. 2 illustrates a cross-section view of an electronic device according to another example.

FIG. 3 illustrates an enclosure for an electronic device having a surface feature extending from a contact surface according to a first example.

FIG. 4 illustrates an enclosure for an electronic device having multiple surface features extending from a contact surface according to a second example.

FIG. 5 illustrates an enclosure for an electronic device having a surface feature extending from a contact surface according to a third example.

FIG. 6 illustrates an enclosure for an electronic device having multiple surface features extending from a contact surface according to a fourth example.

FIG. 7 illustrates an enclosure for an electronic device according to another example.

FIG. 8 illustrates a removable surface feature for an enclosure of an electronic device according to an example.

FIG. 9A-FIG. 9B illustrate an enclosure assembly process using the removable surface feature of FIG. 8 according to an example.

FIG. 9C illustrates how the flexible contact feature of the removable surface feature of FIG. 8 is received into a groove of an enclosure according to an example.

FIG. 10 illustrates a removable surface feature for an enclosure of an electronic device according to another example.

FIG. 11A-FIG. 11B illustrate an enclosure assembly process using the removable surface feature of FIG. 10 according to an example.

### DETAILED DESCRIPTION

In the following detailed description, references are made to the accompanying drawings that form a part hereof, and in which are shown by way of illustrations specific embodiments or examples. These aspects may be combined, other aspects may be utilized, and structural changes may be made without departing from the present disclosure. The following detailed description is therefore not to be taken in a limiting sense, and the scope of the present disclosure is defined by the appended claims and their equivalents.

Electronic devices, such as data storage devices, typically include safe and reliable pathways that enable electric currents to pass through without causing damage to sensitive electronic components. For example, circuit layout designs and/or grounding path designs are typically implemented on a printed circuit board (PCB) of the electronic device to reduce the risk of electrical interference.

In addition to the layout of the circuits and the grounding designs, the design of an enclosure of the electronic device also helps mitigate negative effects of electromagnetic interference. For example, consistent contact between the PCB and the enclosure, and consistent contact between different sections or portions of the enclosure, help ensure the electronic device has optimal protection from electrical interference.

For example, if the electronic device is a data storage device and the data storage device is placed in a server, an outer surface of the enclosure contacts a server carrier. The server carrier is connected to the ground to dissipate unwanted electrical charge that may build up on the data storage device. Likewise, the enclosure to PCB contact serves as a ground for the PCB. In short, the enclosure of the electronic device serves or acts as a Faraday cage or shield for the PCB and blocks electromagnetic fields and other electronic interferences.

However, and as previously explained, due to inherent manufacturing tolerances in the various components associated with the electronic device, contact between the enclosure and the PCB and/or contact between different sections of the enclosure may not always occur. This leads to the loss of Faraday cage effectiveness and/or the loss of the grounding of the PCB.

To address the above, the present disclosure describes an enclosure for an electronic device. As will be explained in greater detail herein, the enclosure includes one or more surface features that account for any manufacturing tolerances associated with the enclosure itself and/or manufacturing tolerances of components (e.g., screws, printed circuit boards (PCBs)) that are associated with the enclosure.

For example, the enclosure includes at least two different portions-a first portion and a second portion. The first portion and the second portion are configured or adapted to mate with each other. The surface feature is provided on, or is otherwise associated with, a contact surface of the first portion of the enclosure and/or the second portion of the enclosure. The surface feature protrudes or extends from the contact surface of the first portion of the enclosure and/or the second portion of the enclosure and contacts the contact surface of the other of the first portion of the enclosure and/or the second portion of the enclosure. As a result, the different portions of the enclosure, or the enclosure and the PCB, remain in contact with each other despite any manufacturing tolerances that may be present.

Accordingly, many technical benefits may be realized including, but not limited to, improving the electromagnetic shielding of an enclosure of an electronic device without increasing the complexity of manufacturing and/or assembly of the electronic device and reducing the complexity of electromagnetic shielding implementations when compared with current solutions (e.g., solder bump implementations).

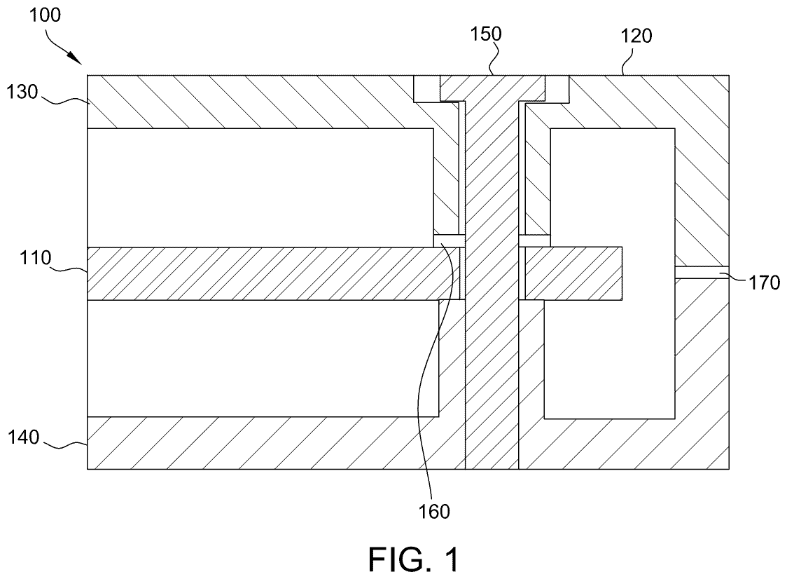

These and other examples will be shown and described in greater detail with respect to FIG. 1-FIG. 11B.

FIG. 1 illustrates a cross-section view of an electronic device 100 according to an example. In an example, the electronic device 100 is a data storage device. Although a data storage device is specifically mentioned, the electronic device 100 may be any type of electronic device, electronic component, computing device and the like.

The electronic device 100 includes a printed circuit board 110 housed within an enclosure 120. In this example, the enclosure 120 includes a first portion 130 and a second portion 140. A horizontal edge or portion of the first portion 130 of the enclosure 120 contacts a horizontal edge of portion of the second portion 140 of the enclosure 120. A screw 150 or other fastener extends between the first portion 130 of the enclosure 120 and the second portion 140 of the enclosure 120 to secure each portion together.

However, due to manufacturing tolerances in one or more of the PCB 110, the first portion 130 of the enclosure 120, the second portion 140 of the enclosure 120 and/or the screw 150, one or more portions of the enclosure 120 may not come into contact with at least a portion of the PCB 110 (represented as gap 160). In another example, and due to manufacturing tolerances, the first portion 130 of the enclosure 120 may not fully contact the second portion 140 of the enclosure 120 (resulting in a gap 170). As previously explained, the gap 160 and/or the gap 170 leads to the loss of Faraday cage effectiveness and/or the loss of PCB grounding.

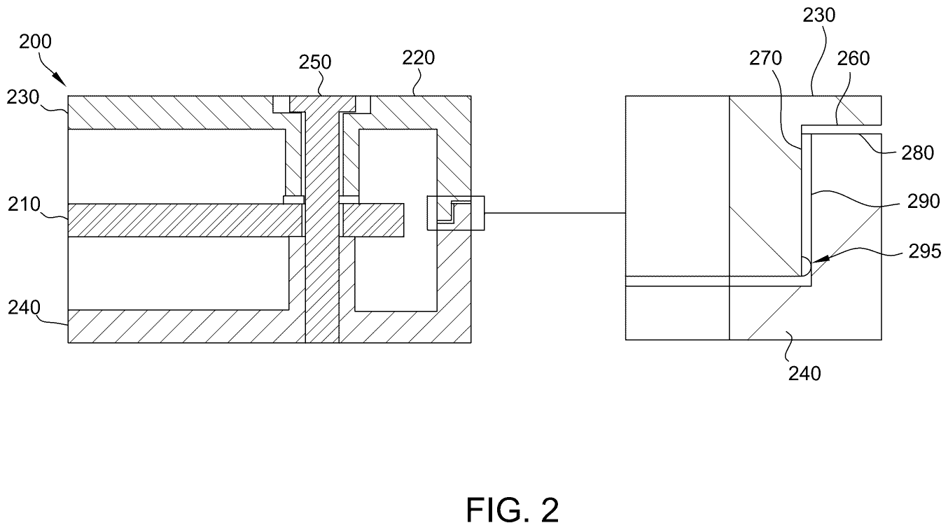

FIG. 2 illustrates a cross-section view of an electronic device 200 according to another example. In an example, the electronic device 200 is a data storage device. Although a data storage device is specifically mentioned, the electronic device 200 may be any type of electronic device, electronic component, computing device and the like.

Like the example shown in FIG. 1, the electronic device 200 includes a PCB 210 housed within an enclosure 220. In an example, the enclosure 220 includes a first portion 230 and a second portion 240. The first portion 230 of the enclosure 220 is configured or adapted to mate with the second portion 240 of the enclosure 220. Additionally, a screw 250 or fastener extends through the first portion 230 of the enclosure 220, the PCB 210 and/or the second portion 240 of the enclosure 220 to secure the first portion 230 of the enclosure 220 to the second portion 240 of the enclosure 220.

However, unlike the example shown in FIG. 1, in this example, each of the first portion 230 of the enclosure 220 and the second portion 240 of the enclosure 220 include an edge, a side or a portion having a stairstep configuration. For example, the first portion 230 of the enclosure 220 includes at least one horizontal contact surface 260 and at least one vertical contact surface 270. Likewise, the second portion 240 of the enclosure 220 includes at least one horizontal contact surface 280 and at least one vertical contact surface 290. Although the stairstep configuration is shown at or near an edge or a perimeter of the enclosure 220, it is contemplated that the stairstep configuration may be placed or located at other areas on or within the various portions of the enclosure 220.

To account for manufacturing tolerances that may be present or otherwise associated with the PCB 210, the first portion 230 of the enclosure 220, the second portion 240 of the enclosure 220 and/or the screw 250, the first portion 230 of the enclosure 220 and/or the second portion 240 of the enclosure 220 includes a surface feature 295.

The surface feature 295 is made from any material. For example, the surface feature 295 is made from copper. In another example, the surface feature 295 is made from the same material as the enclosure 220. Although specific materials are mentioned, other materials, or combinations of materials, may be used. For example, the surface feature 295 is made or comprised of electrically conductive material. As a result, the surface feature 295 forms a conductive path through which electrical charges can pass (e.g., from the first portion 230 of the enclosure 220 to the second portion 240 of the enclosure 220).

In an example, the surface feature 295 extends from, or is part of, or is removably coupled to, a contact surface of the first portion 230 of the enclosure 220 and/or the second portion 240 of the enclosure 220. The surface feature 295 acts as a contact point between the different portions of the enclosure 220.

For example and as shown in FIG. 2, the surface feature 295 extends from the vertical contact surface 270 of the first portion 230 of the enclosure 220 and contacts a vertical contact surface 290 of the second portion 240 of the enclosure 220. Although FIG. 2 illustrates the surface feature 295 extending from the vertical contact surface 270 of the first portion 230 of the enclosure 220, as previously indicated, the surface feature 295 may extend from the horizontal contact surface 260 of the first portion 230 of the enclosure 220. In another example, the surface feature 295 extends from the vertical contact surface 290 of the second portion 240 of the enclosure 220 and/or the horizontal contact surface 280 of the second portion 240 of the enclosure 220.

In yet other examples, any of the contact surfaces of the first portion 230 of the enclosure 220 and/or the second portion 240 of the enclosure 220 include multiple surface features. For example, the vertical contact surface 270 of the first portion 230 of the enclosure 220 can include multiple surface features 295. In another example, the vertical contact surface 270 of the first portion 230 of the enclosure 220 and the vertical contact surface 290 of the second portion 240 of the enclosure 220 can include one or more surface features extending therefrom.

In an example, the surface feature 295 is rounded. In another example, the surface feature 295 is flat. Although specific shapes are mentioned, the surface feature 295 can have any shape. Additionally, the surface feature 295 can have any size (e.g., length, height and/or width) and/or orientation. For example, the surface feature 295 can extend entirely, substantially or partially across a contact surface of one or more of the first portion 230 of the enclosure 220 and/or the second portion 240 of the enclosure 220. In another example, multiple surface features 295 are placed proximate (e.g., above, below, side by side) to each other and extend entirely, substantially, or partially across the contact surface of one or more portions of the enclosure 220.

In an example, the shape, size, number, and/or spacing (e.g., when multiple surface features 295 are provided on one or more contact surfaces of the enclosure 220) of the surface feature 295 (or surface features 295) is based, at least in part, on a determined (e.g., using a simulation tool) or anticipated frequency range of the electromagnetic interference wavelength to which the electronic device 200 will be subjected. For example, surface features 295 may be evenly spaced around the perimeter of the enclosure 220. In another example, the size of the surface features 295 are smaller than a wavelength of the signal.

In an example, and regardless of the shape, size, spacing and/or orientation, the surface feature 295, either alone or in combination with the stairstep configuration of the first portion 230 of the enclosure 220 and the second portion 240 of the enclosure 220, accounts for any manufacturing tolerances and helps ensure the first portion 230 of the enclosure 220 is in contact with the PCB 210 and/or the second portion 240 of the enclosure 220 and vice versa. As a result, the enclosure 220 effectively and efficiently blocks electromagnetic fields and other electronic interferences to which the electronic device 200 is subjected.

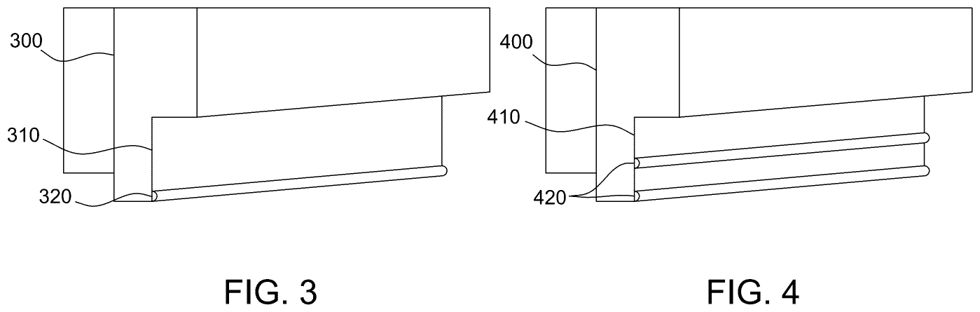

FIG. 3 illustrates an enclosure 300 for an electronic device having a surface feature 320 extending from a contact surface 310 according to a first example. In an example, the enclosure 300 is similar to the first portion 230 of the enclosure 220 and/or the second portion 240 of the enclosure 220 shown and described with respect to FIG. 2.

In this example, the surface feature 320 is a single horizontal bump that extends entirely across the contact surface 310 of the enclosure 300. Although the surface feature 320 is shown extending entirely across the contact surface 310 of the enclosure 300, it is contemplated that the surface feature 320 may extend partially across the contact surface 310 of the enclosure 300. Additionally, although the surface feature 320 is shown extending across a vertical contact surface of the enclosure 300, it is contemplated that the surface feature 320 can extend entirely or partially across a horizontal contact surface of the enclosure 300. In an example, the size, shape, and/or orientation of the surface feature 320 is based, at least in part, on the frequency range of the electromagnetic interference wavelength to which an electronic device that uses the enclosure 300 will be subjected.

FIG. 4 illustrates an enclosure 400 for an electronic device having multiple surface features 420 extending from a contact surface 410 according to a second example. In an example, the enclosure 400 is similar to the first portion 230 of the enclosure 220 and/or the second portion 240 of the enclosure 220 shown and described with respect to FIG. 2.

In this example, each of the multiple surface features 420 are horizontal bumps that extend entirely across the contact surface 410 of the enclosure 400. Although the surface features 420 are shown extending entirely across the contact surface 410 of the enclosure 400, it is contemplated that one or more of the surface features 420 extend partially across the contact surface 410. Additionally, although the surface features 420 are shown extending across a vertical contact surface of the enclosure 400, it is contemplated that one or more of the surface features 420 can extend entirely or partially across a horizontal contact surface of the enclosure 400. In another example, one of the surface features 420 extends partially or entirely across the vertical contact surface of the enclosure 400 and one of the surface features 420 extends partially or entirely across the horizontal contact surface of the enclosure 400. In an example, the size, shape, spacing and/or orientation of the surface features 420 is based, at least in part, on the frequency range of the electromagnetic interference wavelength to which an electronic device that uses the enclosure 400 will be subjected.

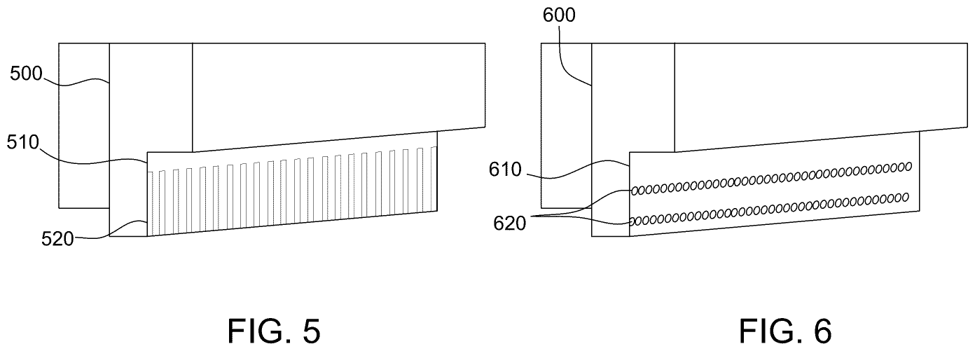

FIG. 5 illustrates an enclosure 500 for an electronic device having a surface feature 520 extending from a contact surface 510 according to a third example. In an example, the enclosure 500 is similar to the first portion 230 of the enclosure 220 and/or the second portion 240 of the enclosure 220 shown and described with respect to FIG. 2.

In this example, the surface feature 520 is multiple vertical bumps that extend from a first portion or edge of the contact surface 510 of the enclosure 500 to a second portion of the contact surface 510 of the enclosure 500. In an example, the vertical bumps are equally spaced apart from one another across the entire length of the contact surface 510 of the enclosure 500. Although the surface features 520 are shown extending entirely across the contact surface 510 of the enclosure 500, it is contemplated that the surface features 520 extend partially across the contact surface 510 of the enclosure 500. Additionally, although the surface features 520 are shown extending across a vertical contact surface, it is contemplated that the surface features 520 can extend entirely or partially across a horizontal contact surface of the enclosure 500. In an example, the size, shape, spacing and/or orientation of the surface features 520 is based, at least in part, on the frequency range of the electromagnetic interference wavelength to which an electronic device that uses the enclosure 500 will be subjected.

FIG. 6 illustrates an enclosure 600 for an electronic device having multiple surface features 620 extending from a contact surface 610 according to a fourth example. In an example, the enclosure 600 is similar to the first portion 230 of the enclosure 220 and/or the second portion 240 of the enclosure 220 shown and described with respect to FIG. 2.

In this example, each of the multiple surface features 620 are dotted bumps that extend entirely across the contact surface 610 of the enclosure 600. Although the surface features 620 are shown extending entirely across the contact surface 610, it is contemplated that one or more of the surface features 620 extend partially across the contact surface 610. Additionally, although the surface features 620 are shown extending across a vertical contact surface of the enclosure 600, it is contemplated that one or more of the surface features 620 can extend entirely or partially across a horizontal contact surface of the enclosure 600.

In another example, one of the surface features 620 extends partially or entirely across the vertical contact surface of the enclosure 600 and one of the surface features 620 extends partially or entirely across the horizontal contact surface of the enclosure 600. In an example, each of the dotted bumps are equally spaced apart from one another. Additionally, the size, shape, spacing and/or orientation of the surface features 620 is based, at least in part, on the frequency range of the electromagnetic interference wavelength to which an electronic device that uses the enclosure 600 will be subjected.

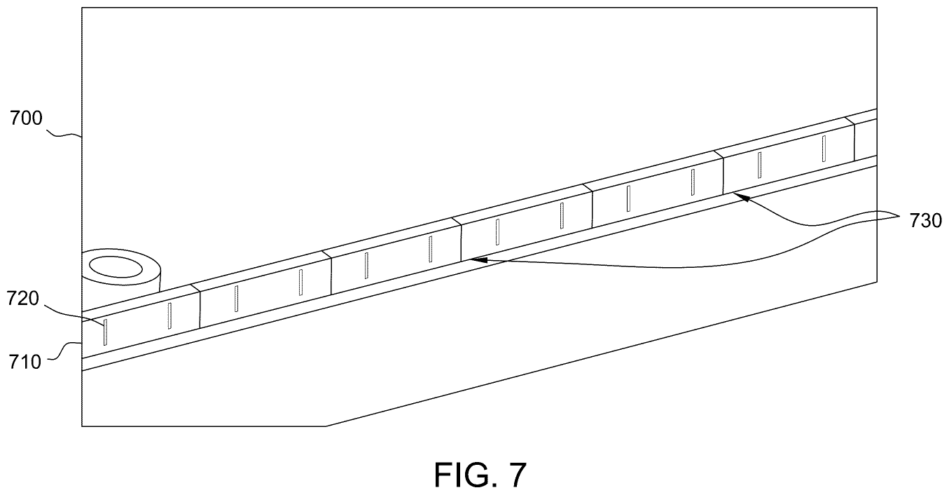

FIG. 7 illustrates an enclosure 700 for an electronic device according to another example. In an example, the enclosure 700 is similar to the first portion 230 of the enclosure 220 and/or the second portion 240 of the enclosure 220 shown and described with respect to FIG. 2.

In this example, at least one contact surface 710 of the enclosure 700 includes slits 730 or grooves. The slits 730 reduce the localized stiffness of the enclosure 700 at or near the contact surface 710. As a result, the contact surface 710 may bend or move during assembly of the enclosure. In another example, the contact surface 710 of the enclosure may be tapered. For example, a first portion of the contact surface 710 may have a first dimension and a second portion of the contact surface 710 may have a second dimension that is smaller (or larger) than the first dimension. In addition to the slits 730, the contact surface 710 also includes one or more surface features 720 that act as contact points between different portions of the enclosure such as previously described.

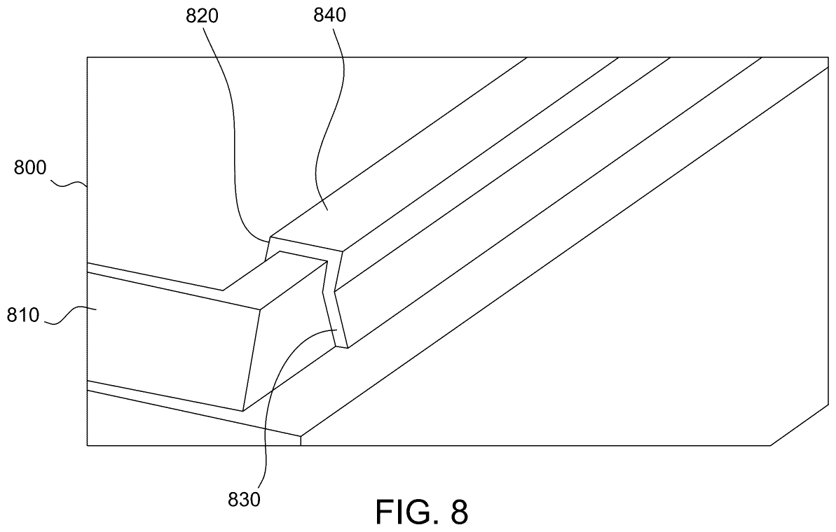

FIG. 8 illustrates a removable surface feature 820 for an enclosure 800 of an electronic device according to an example. In an example, the enclosure 800 is similar to the first portion 230 of the enclosure 220 and/or the second portion 240 of the enclosure 220 shown and described with respect to FIG. 2. For example, the enclosure 800 includes a contact surface 810 that is configured in a stairstep configuration.

In the example shown in FIG. 8, the removable surface feature 820 is a clip-on surface feature. In an example, the removable surface feature 820 is made of copper. In another example, the removable surface feature 820 is made from the same material as the enclosure 800. In yet another example, the removable surface feature 820 is made from any conductive material or combination of materials.

In an example, a body portion 840 of the removable surface feature 820 clips on, or otherwise attaches to, a vertical (or horizontal) contact surface 810 of the enclosure 800. Additionally, a flexible contact feature 830 extends from the body portion 840 of the removable surface feature 820 and acts as a contact point. The flexible contact feature 830 may extend entirely along the body portion 840 of the removable surface feature 820. In other examples, the flexible contact feature 830 is divided into sections or portions. In an example, the flexible contact feature 830 moves from a first state (e.g., a non-compressed state) to a second state (e.g., a compressed state) when the enclosure 800 mates with another enclosure.

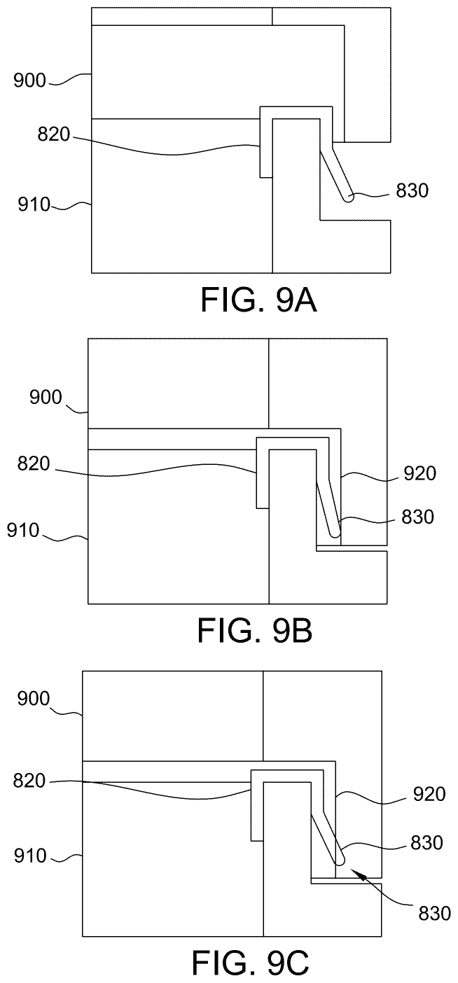

FIG. 9A-FIG. 9B illustrate an enclosure assembly process using the removable surface feature 820 of FIG. 8 according to an example. As shown in FIG. 9A, the removable surface feature 820 is removably coupled to a contact surface of a first portion of an enclosure 910. In an example, the first portion of the enclosure 910 is similar to the enclosure 800 shown and described with respect to FIG. 8.

During the assembly process, a second portion of an enclosure 900 is positioned above or proximate to the first portion of the enclosure 910. As shown in FIG. 9A, the flexible contact feature 830 of the removable surface feature 820 is in a first state (e.g., a non-compressed or non-deformed state).

However, and as shown in FIG. 9B, when the second portion of the enclosure 900 mates with the first portion of the enclosure 910, a contact surface (e.g., a vertical contact surface 920) of the second portion of the enclosure 900 contacts the flexible contact feature 830 of the removable surface feature 820. The contact causes the flexible contact feature 830 to move from the first state to a second state (e.g., a compressed or a deformed state). When in the second state, the flexible contact feature 830 remains in contact with the vertical contact surface 920 of the second portion of the enclosure 900.

In an example, and as shown in FIG. 9C, a contact surface (e.g., the vertical contact surface 920) of the second portion of the enclosure 900 includes a groove 930. The groove 930 acts as a locking feature and receives at least a portion of the flexible contact feature 830 of the removable surface feature 820 when the first portion of the enclosure 910 mates with the second portion of the enclosure 900.

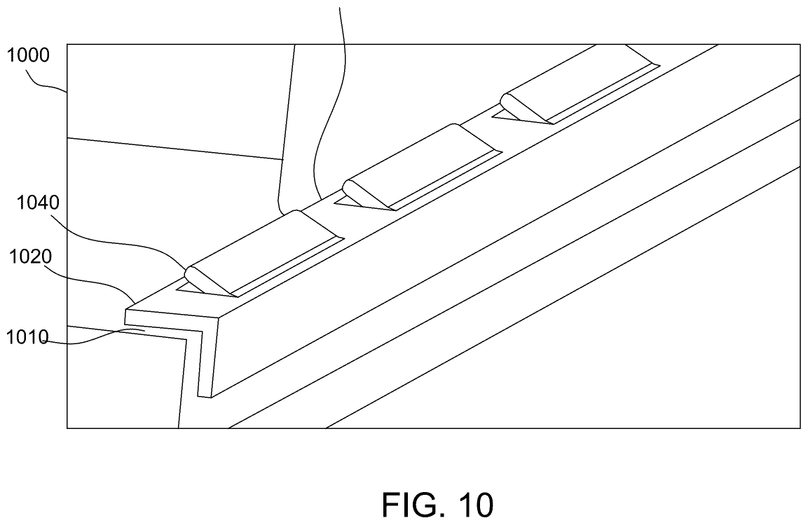

FIG. 10 illustrates a removable surface feature 1020 for an enclosure 1000 of an electronic device according to another example. In an example, the enclosure 1000 is similar to the first portion 230 of the enclosure 220 and/or the second portion 240 of the enclosure 220 shown and described with respect to FIG. 2. For example, the enclosure 1000 includes a contact surface 1010 that is configured in a stairstep configuration.

In this example, the removable surface feature 1020 is provided on a horizontal contact surface 1010 of the enclosure 1000 (instead of a vertical contact surface such as shown in FIG. 8). For example a body portion 1040 of the removable surface feature 1020 is removably attached to at least a portion of the horizontal contact surface 1010 of the enclosure 1000.

In an example, the removable surface feature 1020 is made of copper. In another example, the removable surface feature 1020 is made from the same material as the enclosure 1000. In yet another example, the removable surface feature 1020 is made from any conductive material or combination of materials.

In an example, a flexible contact feature 1030 extends from the body portion 1040 of the removable surface feature 1020. The flexible contact feature 1030 may extend entirely along the body portion 1040 of the removable surface feature 1020. In other examples, such as shown in FIG. 10, the flexible contact feature 1030 is divided into sections or portions. One or more of the portions of the flexible contact feature 1030 act as contact points for the different portions or sections of the enclosure. In an example, the flexible contact feature 1030 moves from a first state (e.g., a non-compressed state) to a second state (e.g., a compressed state) when the enclosure 1000 mates with another enclosure.

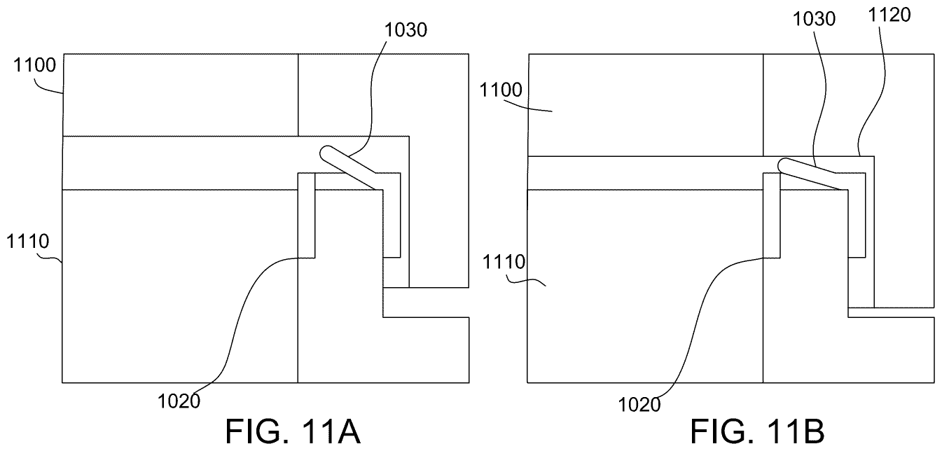

FIG. 11A-FIG. 11B illustrate an enclosure assembly process using the removable surface feature 1020 of FIG. 10 according to an example. As shown in FIG. 11A, the removable surface feature 1020 is removably coupled to a horizontal contact surface of a first portion of an enclosure 1110. In an example, the first portion of the enclosure 1110 is similar to the enclosure 1000 shown and described with respect to FIG. 10.

During the assembly process, a second portion of an enclosure 1100 is positioned above or proximate to the first portion of the enclosure 1110. As shown in FIG. 9A, the flexible contact feature 1030 of the removable surface feature 1020 is in a first state (e.g., a non-compressed or non-deformed state). However, and as shown in FIG. 11B, when the second portion of the enclosure 1100 mates with the first portion of the enclosure 1110, a contact surface (e.g., a horizontal contact surface 1120) of the second portion of the enclosure 1100 contacts the flexible contact feature 1030 of the removable surface feature 1020. The contact causes the flexible contact feature 1030 to move from the first state to a second state (e.g., a compressed or a deformed state). When in the second state, the flexible contact feature 1030 remains in contact with the horizontal contact surface 1120 of the second portion of the enclosure 1100.

Based on the above, examples of the present disclosure describe an enclosure for an electronic device, comprising: a first section having a first contact surface in a first stairstep configuration; a second section having a second contact surface in a second stairstep configuration that mates with the first contact surface of the first section; and a surface feature extending from the first contact surface, the surface feature providing a contact point between the first contact surface and the second contact surface. In an example, the surface feature is provided on a horizontal portion of the first contact surface. In an example, the surface feature is provided on a vertical portion of the first contact surface. In an example, the surface feature extends partially across the first contact surface. In an example, the surface feature extends entirely across the first contact surface. In an example, at least one of the first contact surface and the second contact surface includes one or more slits. In an example, at least one of the first contact surface and the second contact surface is tapered. In an example, the surface feature is removably coupled to the first contact surface. In an example, the surface feature is comprised of an electrically conductive material. In an example, the second contact surface comprises a groove that receives at least a portion of the surface feature.

Examples also describe an enclosure for an electronic device, comprising: a first portion; a second portion adapted to mate with the first portion; and a plurality of surface features extending from a perimeter of at least one of the first portion and the second portion, the plurality of surface features providing a contact point between the first portion and the second portion. In an example, at least one of a size, a shape, a spacing and a number of the plurality of surface features is based, at least in part, on a frequency range of an electromagnetic interference wavelength to which the electronic device is subjected. In an example, at least one of the plurality of surface features extend from a vertical contact surface of the at least one of the first portion and the second portion. In an example, at least a portion of each of the plurality of surface features are received into a groove associated with at least one of the first portion and the second portion when the first portion is mates with the second portion. In an example, the plurality of surface features are associated with a removable clip. In an example, the removable clip is comprised of electrically conductive material.

Examples also describe an enclosure for an electronic device, comprising: a first section having a first contact surface; a second section having a second contact surface that mates with the first contact surface of the first section; and a surface feature associated with the first contact surface, the surface feature: accounting for a manufacturing tolerance associated with at least one of the first section and the second section; and providing a contact point between the first contact surface and the second contact surface. In an example, the surface feature extends partially across the first contact surface. In an example, the surface feature is a first surface feature and wherein a second surface feature is proximate the first surface feature. In an example, the second surface feature is positioned above the first surface feature.

The description and illustration of one or more aspects provided in the present disclosure are not intended to limit or restrict the scope of the disclosure in any way. The aspects, examples, and details provided in this disclosure are considered sufficient to convey possession and enable others to make and use the best mode of claimed disclosure.

The claimed disclosure should not be construed as being limited to any aspect, example, or detail provided in this disclosure. Regardless of whether shown and described in combination or separately, the various features (both structural and methodological) are intended to be selectively rearranged, included or omitted to produce an embodiment with a particular set of features. Having been provided with the description and illustration of the present application, one skilled in the art may envision variations, modifications, and alternate aspects falling within the spirit of the broader aspects of the general inventive concept embodied in this application that do not depart from the broader scope of the claimed disclosure.

Aspects of the present disclosure have been described above with reference to schematic flowchart diagrams and/or schematic block diagrams of methods, apparatuses, systems, and computer program products according to embodiments of the disclosure. It will be understood that each block of the schematic flowchart diagrams and/or schematic block diagrams, and combinations of blocks in the schematic flowchart diagrams and/or schematic block diagrams, can be implemented by computer program instructions. These computer program instructions may be provided to a processor of a computer or other programmable data processing apparatus to produce a machine, such that the instructions, which execute via the processor or other programmable data processing apparatus, create means for implementing the functions and/or acts specified in the schematic flowchart diagrams and/or schematic block diagrams block or blocks. Additionally, it is contemplated that the flowcharts and/or aspects of the flowcharts may be combined and/or performed in any order.

References to an element herein using a designation such as “first,” “second,” and so forth does not generally limit the quantity or order of those elements. Rather, these designations may be used as a method of distinguishing between two or more elements or instances of an element. Thus, reference to first and second elements does not mean that only two elements may be used or that the first element precedes the second element. Additionally, unless otherwise stated, a set of elements may include one or more elements.

Terminology in the form of “at least one of A, B, or C” or “A, B, C, or any combination thereof” used in the description or the claims means “A or B or C or any combination of these elements.” For example, this terminology may include A, or B, or C, or A and B, or A and C, or A and B and C, or 2A, or 2B, or 2C, or 2A and B, and so on. As an additional example, “at least one of: A, B, or C” is intended to cover A, B, C, A-B, A-C, B-C, and A-B-C, as well as multiples of the same members. Likewise, “at least one of: A, B, and C” is intended to cover A, B, C, A-B, A-C, B-C, and A-B-C, as well as multiples of the same members.

Similarly, as used herein, a phrase referring to a list of items linked with “and/or” refers to any combination of the items. As an example, “A and/or B” is intended to cover A alone, B alone, or A and B together. As another example, “A, B and/or C” is intended to cover A alone, B alone, C alone, A and B together, A and C together, B and C together, or A, B, and C together.

What is claimed is:

1. An enclosure for an electronic device, comprising:
a first section having a first contact surface in a first stairstep configuration;
a second section having a second contact surface in a second stairstep configuration that mates with the first contact surface of the first section; and
a surface feature extending from the first contact surface, the surface feature providing a contact point between the first contact surface and the second contact surface.

2. The enclosure of claim 1, wherein the surface feature is provided on a horizontal portion of the first contact surface.

3. The enclosure of claim 1, wherein the surface feature is provided on a vertical portion of the first contact surface.

4. The enclosure of claim 1, wherein the surface feature extends partially across the first contact surface.

5. The enclosure of claim 1, wherein the surface feature extends entirely across the first contact surface.

6. The enclosure of claim 1, wherein at least one of the first contact surface and the second contact surface includes one or more slits.

7. The enclosure of claim 1, wherein at least one of the first contact surface and the second contact surface is tapered.

8. The enclosure of claim 1, wherein the surface feature is removably coupled to the first contact surface.

9. The enclosure of claim 1, wherein the surface feature is comprised of an electrically conductive material.

10. The enclosure of claim 1, wherein the second contact surface comprises a groove that receives at least a portion of the surface feature.

11. An enclosure for an electronic device, comprising:
a first portion;
a second portion adapted to mate with the first portion; and
a plurality of surface features extending from a perimeter of at least one of the first portion and the second portion, the plurality of surface features providing a contact point between the first portion and the second portion.

12. The enclosure of claim 11, wherein at least one of a size, a shape, a spacing and a number of the plurality of surface features is based, at least in part, on a frequency range of an electromagnetic interference wavelength to which the electronic device is subjected.

13. The enclosure of claim 11, wherein at least one of the plurality of surface features extend from a vertical contact surface of the at least one of the first portion and the second portion.

14. The enclosure of claim 11, wherein at least a portion of each of the plurality of surface features are received into a groove associated with at least one of the first portion and the second portion when the first portion is mates with the second portion.

15. The enclosure of claim 11, wherein the plurality of surface features are associated with a removable clip.

16. The enclosure of claim 15, wherein the removable clip is comprised of electrically conductive material.

17. An enclosure for an electronic device, comprising:
a first section having a first contact surface;
a second section having a second contact surface that mates with the first contact surface of the first section; and
a surface feature associated with the first contact surface, the surface feature:
accounting for a manufacturing tolerance associated with at least one of the first section and the second section; and
providing a contact point between the first contact surface and the second contact surface.

18. The enclosure of claim 17, wherein the surface feature extends partially across the first contact surface.

19. The enclosure of claim 17, wherein the surface feature is a first surface feature and wherein a second surface feature is proximate the first surface feature.

20. The enclosure of claim 19, wherein the second surface feature is positioned above the first surface feature.
